(19) United States
(12) Patent Application Publication
(10) Pub. No.: US 2012/0248404 A1
(43) Pub. Date: Oct. 4, 2012

(54) GALLIUM-NITRIDE LIGHT EMITTING DIODE AND MANUFACTURING METHOD THEREOF

(75) Inventors: Jong Moo LEE, Daejeon (KR); Han Youl RYU, Incheon (KR); Eun Soo NAM, Daejeon (KR); Sung Bum BAE, Daejeon (KR)

(73) Assignee: ELECTRONICS AND TELECOMMUNICATIONS RESEARCH INSTITUTE, Daejeon (KR)

(21) Appl. No.: 13/406,544

(22) Filed: Feb. 28, 2012

(30) Foreign Application Priority Data
Apr. 1, 2011 (KR) 10-2011-0030041

(51) Int. Cl. H01L 33/04; H01L 33/32

(52) U.S. Cl. 257/13; 438/47; 257/E33.008; 257/E33.023

(57) ABSTRACT

The present disclosure relates to a gallium-nitride light emitting diode and a manufacturing method thereof and the gallium-nitride light emitting diode includes an n-type nitride semiconductor layer formed on a substrate; an active layer formed on the n-type nitride semiconductor layer; a p-type doped intermediate layer formed on the active layer; and a p-type nitride semiconductor layer formed on the intermediate layer.

### CROSS-REFERENCE TO RELATED APPLICATIONS

This application is based on and claims priority from Korean Patent Application No. 10-2011-0030041, filed on Apr. 1, 2011, with the Korean Intellectual Property Office, the present disclosure of which is incorporated herein in its entirety by reference.

### TECHNICAL FIELD

The present disclosure relates to a light emitting diode, and more particularly, to a gallium-nitride light emitting diode for overcoming an efficiency droop phenomenon in which light-emitting efficiency is reduced as driving current increases by making hole transfer smooth in implementing the gallium-nitride light emitting diode, and a manufacturing method thereof.

### BACKGROUND

Currently, the biggest obstacle in the light emitting diode (LED) lighting industry is an efficiency droop phenomenon in which light-emitting efficiency is deteriorated when driving an LED at high current. In order to revitalize the LED lighting industry, the efficiency droop phenomenon needs to be overcome and price competitiveness of high efficiency and high power LEDs needs to be enhanced.

The efficiency droop phenomenon of LEDs refers to a phenomenon in which light-emitting efficiency drops sharply as a current density increases. It is desirable to maintain light-emitting efficiency of more than 80 lm/W (corresponding to the efficiency of fluorescent light) close to the efficiency of driving at low current even while driving at high current of 1 A based on an LED chip having a size of 1 mm×1 mm, but with the current LED technology, light-emitting efficiency is sharply reduced to under half while driving at current of 1 A as shown in FIG. 1.

Diversified researches have been conducted all over the world to overcome the efficiency droop phenomenon of the LEDs, but no obvious solution has yet been discovered while the factors leading to the efficiency droop phenomenon have not yet been clearly analyzed.

### SUMMARY

The present disclosure has been made in an effort to provide a gallium-nitride light emitting diode for overcoming an efficiency droop phenomenon in which light-emitting efficiency is reduced as driving current increases by making hole transfer smooth in implementing the gallium-nitride light emitting diode, and a manufacturing method thereof.

An exemplary embodiment of the present disclosure provides a gallium-nitride light emitting diode, including: an n-type nitride semiconductor layer formed on a substrate; an active layer formed on the n-type nitride semiconductor layer; a p-type doped intermediate layer formed on the active layer; and a p-type nitride semiconductor layer formed on the intermediate layer.

Another exemplary embodiment of the present disclosure provides a method of manufacturing a gallium-nitride light emitting diode, including: forming an n-type nitride semiconductor layer on a substrate; forming an active layer on the n-type nitride semiconductor layer; forming a p-type doped intermediate layer on the active layer; and forming a p-type nitride semiconductor layer on the intermediate layer.

According to exemplary embodiments of the present disclosure, by providing the gallium-nitride light emitting diode further including the intermediate layer serving as a buffer between the active layer and the p-type nitride semiconductor layer and the manufacturing method thereof, it is possible to overcome an efficiency droop phenomenon in which efficiency is deteriorated when driving the gallium-nitride light emitting diode at high current, which may increase price competitiveness of high power light emitting diodes.

The gallium-nitride light emitting diode according to the present disclosure does not require an AlGaN EBL (electron blocking layer), which enables growth at a low growth temperature and high-quality epitaxial growth.

Since the intermediate layer of the gallium-nitride light emitting diode according to the present disclosure may be effectively doped even at a relatively low p-type doping concentration, it is not required to dope a p-type doping material such as Mg and Zn at a high concentration.

In the gallium-nitride light emitting diode according to the present disclosure, since the p-type nitride semiconductor layer doped at a high concentration is separated from a multi quantum well (MQW), it is possible to prevent diffusion of a p-type dopant from the p-type nitride semiconductor layer to the MQW.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a graph illustrating a phenomenon in which light-emitting efficiency is deteriorated as driving current increases in a light emitting diode of the related art.

FIG. 2 is a lateral cross-sectional view illustrating a gallium-nitride light emitting diode according to an exemplary embodiment of the present disclosure.

FIGS. 3A to 3E are a process flowchart illustrating a method of manufacturing a gallium-nitride light emitting diode according to an exemplary embodiment of the present disclosure.

FIG. 4 is a graph showing an effect of overcoming an efficiency droop phenomenon by including a p-type doped intermediate layer in the gallium-nitride light emitting diode according to the exemplary embodiment of the present disclosure to improve internal quantum efficiency (hereinafter, referred to as ‘IQE’) at a high current density.

FIGS. 5A and 5B are a graph showing an effect of overcoming an efficiency droop phenomenon by including a p-type doped intermediate layer in the gallium-nitride light emitting diode according to the exemplary embodiment of the present disclosure to improve the IQE at a high current density regardless of the Al composition of an AlₓGa₁₋ₓN EBL (electron blocking layer).

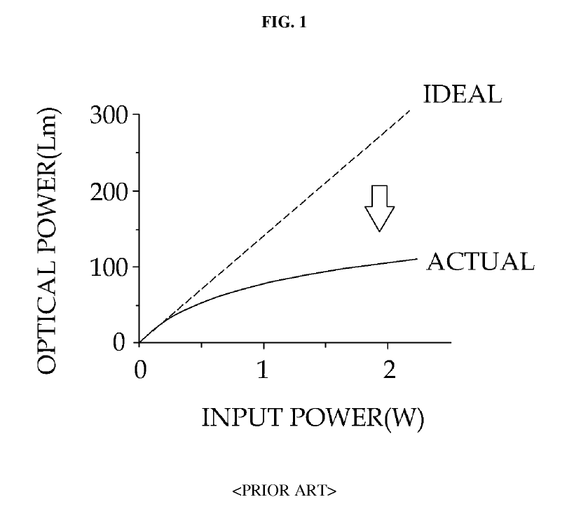

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

Hereinafter, exemplary embodiments of the present disclosure will be described in detail with reference to the accompanying drawings. Further, in describing the present disclosure, well-known functions or constructions will not be described in detail since they may unnecessarily obscure the understanding of the present invention.

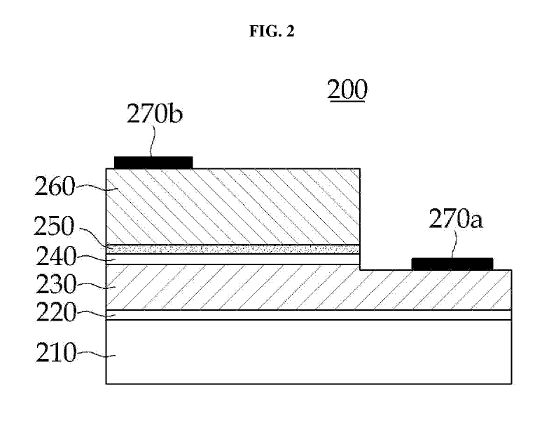

FIG. 2 is a lateral cross-sectional view illustrating a gallium-nitride light emitting diode according to an exemplary embodiment of the present disclosure.

Referring to FIG. 2, a gallium-nitride light emitting diode 200 according to the present disclosure includes a sapphire substrate 210 on which a buffer layer 220 is formed, and an n-type nitride semiconductor layer 230, an active layer 240, and a p-type nitride semiconductor layer 260 that are sequentially formed on the buffer layer 220 of the sapphire substrate 210. Here, the light emitting diode 100 includes n-side and p-side electrodes 270a and 270b each connected to the n-type nitride semiconductor layer 230 and the p-type nitride semiconductor layer 260.

The light emitting diode 100 according to the present disclosure includes a p-type doped intermediate layer 250 between the active layer 240 and the p-type nitride semiconductor layer 260. Here, the intermediate layer 250 may be a material including GaN or InGaN. When the intermediate layer 250 is InGaN, In may be included in InGaN at less than 5%.

A doping concentration of the intermediate layer 250 is lower than that of the p-type nitride semiconductor layer 260. Specifically, a hole concentration of the intermediate layer 250 may be less than 5×10¹⁷ cm⁻³. Here, when the intermediate layer 250 is doped with a material such as Mg or Zn, the doping concentration of the intermediate layer 250 is less than 5×10¹⁸ cm⁻³.

The intermediate layer 250 may be formed to have a thickness of 10 to 100 nm.

The nitride semiconductor layers constituting the light emitting diode 200 according to the present disclosure, that is, the p-type and n-type nitride semiconductor layers 260 and 230 and the active layer 240 are made of GaN, and particularly, the active layer 240 may have a multi quantum well (hereinafter, referred to as ‘MQW’) structure in which a quantum barrier layer of GaN and a quantum well layer of InGaN are alternately stacked several times.

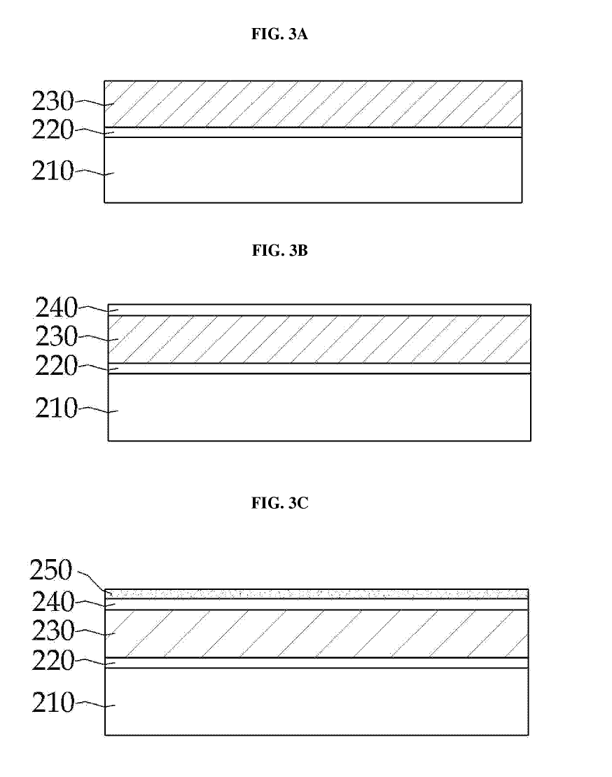

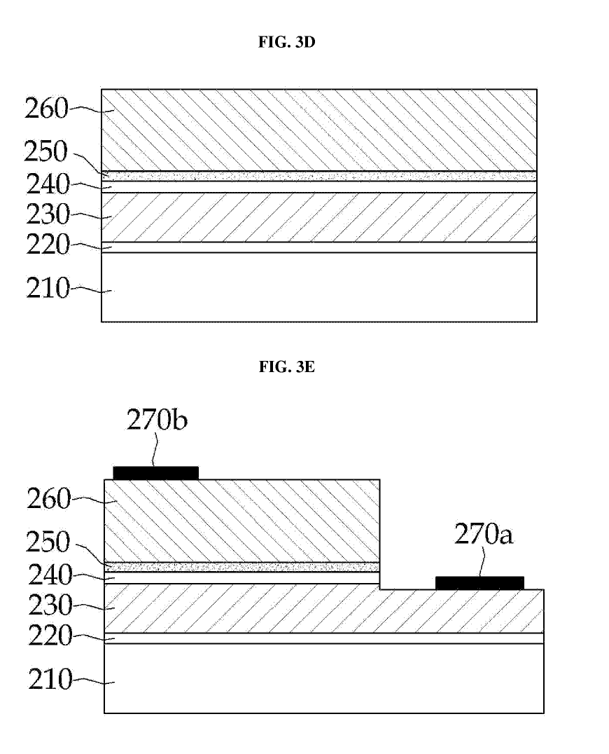

FIGS. 3A to 3E are a process flowchart illustrating a method of manufacturing a gallium-nitride light emitting diode according to an exemplary embodiment of the present disclosure.

Referring to FIG. 3A, after forming an AIN low temperature nucleus growth layer as the buffer layer 220 on the sapphire substrate 210, the n-type nitride semiconductor layer 230 is formed. Here, the n-type nitride semiconductor layer 230 is GaN.

Referring to FIG. 3B, on the n-type nitride semiconductor layer 230, the active layer 240 having the MQW structure is formed by alternately stacking a quantum barrier layer of GaN and a quantum well layer of InGaN several times.

Referring to FIG. 3C, the p-type doped intermediate layer 250 is formed on the active layer 240 to have a thickness of 10 to 100 nm. Here, the intermediate layer 250 may be a material including GaN or InGaN. In this case, when the intermediate layer is InGaN, In may be included in InGaN at less than 5%. A doping concentration of the intermediate layer 250 is lower than that of the p-type nitride semiconductor layer 260. Specifically, a hole concentration of the intermediate layer 250 may be less than 5×10¹⁷ cm⁻³. Here, when the intermediate layer 250 is doped with a material such as Mg or Zn, the doping concentration of the intermediate layer 250 is less than 5×10¹⁸ cm⁻³.

Referring to FIG. 3D, the p-type nitride semiconductor layer 260 is formed on the intermediate layer 250. Here, for the p-type nitride semiconductor layer 260, GaN may be used similarly as in the n-type nitride semiconductor layer 230.

Finally, referring to FIG. 3E, mesa etching is performed so that a top surface of the n-type nitride semiconductor layer 230 is partially exposed and the n-side and p-side electrodes 270a and 270b are formed of the same material on the n-type nitride semiconductor layer 230 and the p-type nitride semiconductor layer 260, respectively.

Therefore, the light emitting diode 200 according to the present disclosure may improve hole transfer by controlling the doping concentration of the intermediate layer 250, and as a result, may overcome an efficiency droop phenomenon. In other words, smooth injection of holes to the MQW allows a hole concentration in the MQW to be increased, and thus light-emitting efficiency may be improved. Since the hole injection to the MQW is smoothly performed, it is possible to reduce driving voltage and achieve high efficiency of the light emitting diode 200. It is also possible to prevent efficiency of the light emitting diode 200 from being deteriorated due to electron leakage by suppressing an overflow of electrons of the MQW to the p-type nitride semiconductor layer 260.

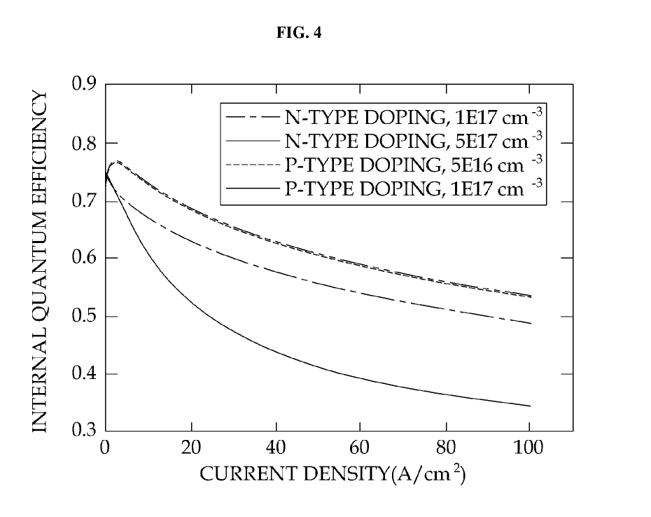

FIG. 4 is a graph showing an effect of overcoming an efficiency droop phenomenon by including a p-type doped intermediate layer in the gallium-nitride light emitting diode according to an exemplary embodiment of the present disclosure to improve internal quantum efficiency (hereinafter, referred to as ‘IQE’) at a high current density.

Referring to FIG. 4, it can be seen that when n-type doping is performed on the intermediate layer 250 of the light emitting diode 200 according to the present disclosure, the efficiency droop phenomenon becomes more serious as the doping concentration increases and when p-type doping is performed on the intermediate layer 250, if a hole concentration is only more than 5×10¹⁶ cm⁻³, the efficiency droop phenomenon is significantly improved.

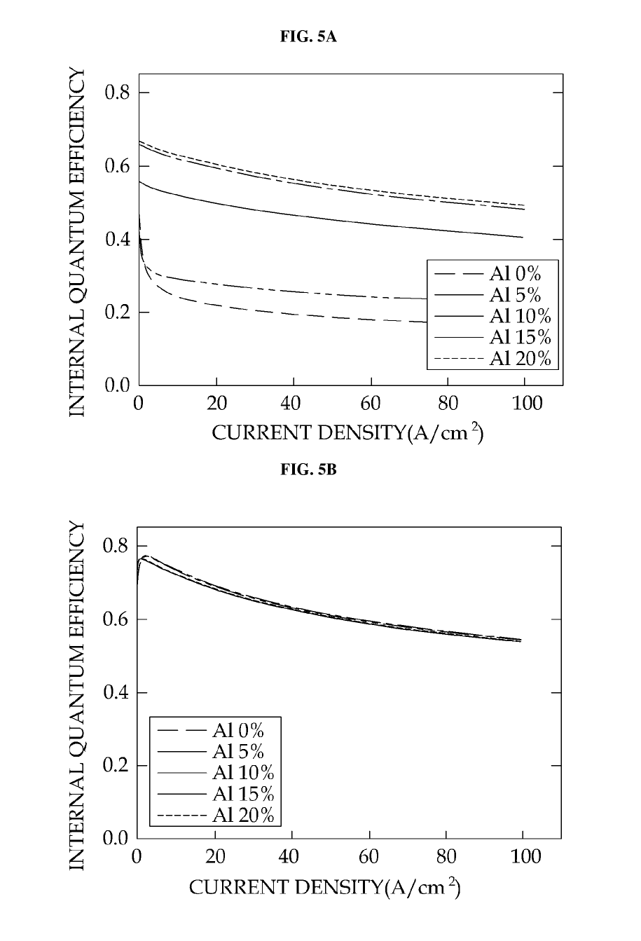

FIGS. 5A and 5B are a graph showing an effect of overcoming an efficiency droop phenomenon by including a p-type doped intermediate layer in the gallium-nitride light emitting diode according to the exemplary embodiment of the present disclosure to improve IQE at a high current density regardless of the Al composition of an AlₓGa₁₋ₓN EBL (electron blocking layer).

Referring to FIG. 5A, it can be seen that when the n-type doping is performed on the intermediate layer 250, as the Al composition of the EBL is reduced, the IQE decreases and an efficiency droop phenomenon becomes more serious. This is because a step of the EBL is lowered as the Al composition is reduced, which leads to severe electron leakage.

Referring to FIG. 5B, it can be seen that when p-type doping is performed on the intermediate layer 250, high IQE is maintained at all times regardless of the Al composition of the EBL and the efficiency droop phenomenon is overcome. That is, even when the Al composition of the EBL is 0, high IQE is maintained, which makes it possible to implement an LED without an AlGaN layer. The LED without an AlGaN layer allows growth at a relatively low temperature and thus enables high quality epitaxial growth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A gallium-nitride light emitting diode, comprising:
an n-type nitride semiconductor layer formed on a substrate;
an active layer formed on the n-type nitride semiconductor layer;
a p-type doped intermediate layer formed on the active layer; and
a p-type nitride semiconductor layer formed on the intermediate layer.

2. The gallium-nitride light emitting diode of claim 1, wherein a doping concentration of the intermediate layer is lower than a doping concentration of the p-type nitride semiconductor layer.

3. The gallium-nitride light emitting diode of claim 1, wherein the intermediate layer is GaN or InGaN.

4. The gallium-nitride light emitting diode of claim 3, wherein when the intermediate layer is InGaN, In of InGaN is less than 5%.

5. The gallium-nitride light emitting diode of claim 1, wherein a thickness of the intermediate layer is 10 to 100 nm.

6. The gallium-nitride light emitting diode of claim 1, wherein a hole concentration of the intermediate layer is less than 5×10¹⁷ cm⁻³.

7. The gallium-nitride light emitting diode of claim 1, wherein the intermediate layer is doped with Mg or Zn.

8. The gallium-nitride light emitting diode of claim 7, wherein a doping concentration of the intermediate layer is less than 5×10¹⁸ cm⁻³.

9. The gallium-nitride light emitting diode of claim 1, wherein the active layer is a multi quantum well layer.

10. A method of manufacturing a gallium-nitride light emitting diode, comprising:
forming an n-type nitride semiconductor layer on a substrate;
forming an active layer on the n-type nitride semiconductor layer;
forming a p-type doped intermediate layer on the active layer; and
forming a p-type nitride semiconductor layer on the intermediate layer.

11. The method of claim 10, wherein a doping concentration of the intermediate layer is lower than a doping concentration of the p-type nitride semiconductor layer.

12. The method of claim 10, wherein in the forming of the intermediate layer, the intermediate layer is formed to have a thickness of 10 to 100 nm.

13. The method of claim 10, wherein in the forming of the intermediate layer, a hole concentration of the intermediate layer is less than 5×10¹⁷ cm⁻³.

14. The method of claim 10, wherein in the forming of the intermediate layer, the intermediate layer is doped with Mg or Zn.

15. The method of claim 14, wherein a doping concentration of the intermediate layer is less than 5×10¹⁸ cm⁻³.
